(19) United States
(12) Patent Application Publication
(10) Pub. No.: US 2017/0365403 A1
(43) Pub. Date: Dec. 21, 2017

(54) PASSIVE ALIGNMENT SYSTEM AND METHOD

(71) Applicant: Evatran Group, Inc., Richmond, VA (US)

(72) Inventor: Thomas Gattan STOUT, II, Morrisville, NC (US)

(21) Appl. No.: 15/624,335

(22) Filed: Jun. 15, 2017

Related U.S. Application Data
(60) Provisional application No. 62/351,153, filed on Jun. 16, 2016.

(51) Int. Cl. H01F 38/14; B60L 11/18; G01R 27/26; H02J 7/02

(52) U.S. Cl. CPC H01F 38/14; H02J 7/025; B60L 11/182; G01R 27/2611

(57) ABSTRACT

An inductive alignment system is provided. The system includes a power source providing a forcing function and a first inductor in communication with the power source. The first inductor exhibits a first electrical property in response to the forcing function. The system also includes a second inductor in communication with the first inductor. The second inductor exhibits a second electrical property in response to the forcing function. The system includes a comparator that compares the first electrical property with the second electrical property and generates a signal based at least in part on a deviation between the first electrical property and the second electrical property. The deviation is caused at least in part by inductive coupling between a proximate object and at least one of the first inductor and the second inductor. A method of inductive alignment using the above system is also provided.

### CROSS-REFERENCE TO RELATED APPLICATIONS

The present disclosure is related and claims priority to U.S. Provisional Pat. Appl. No. 62/351,153, entitled PASSIVE ALIGNMENT SYSTEM, to Thomas Stout, filed on Jun. 16, 2016, the contents of which are hereby incorporated by reference in their entirety, for all purposes.

### BACKGROUND

### Field of Disclosure

Embodiments described herein are generally related to the field of wireless powering of electronic devices. More specifically, embodiments described herein are related to systems and methods for aligning an electronic device relative to a remote power supply for efficient wireless power transfer to the electronic device. One or more of these embodiments may be employed to transfer power to a vehicle from a base charging system.

### Related Art

Current systems for aligning mobile electronic appliances with wireless recharging units make use of radiofrequency identification RFID, mechanical, optical, or visual technologies that rely on high power and/or complex circuitry. The systems are therefore costly, and also tend to interfere with the power transmission process because, e.g., of the use of resonant circuitry. Therefore, it is desirable to have an alignment system that uses low power and has little to no interference with the power transmission process.

### SUMMARY

In one embodiment, an inductive alignment system includes a power source providing a forcing function and a first inductor in communication with the power source. The first inductor exhibits a first electrical property in response to the forcing function. The system also includes a second inductor in communication with the first inductor. The second inductor exhibits a second electrical property in response to the forcing function. The system includes a comparator that compares the first electrical property with the second electrical property and generates a signal based at least in part on a deviation between the first electrical property and the second electrical property. The deviation is caused at least in part by inductive coupling between a proximate object and at least one of the first inductor and the second inductor.

In another embodiment, a method of inductive alignment includes applying a first signal to a first inductor, the first signal provided by a power source and applying a second signal to a second inductor, the second signal provided by the power source. The method also includes measuring a first electrical property of the first inductor in response to the first signal, measuring a second electrical property of the second inductor in response to the second signal, comparing the first electrical property with the second electrical property, and generating a third signal based at least in part on a deviation between the first electrical property and the second electrical property. The deviation is caused at least in part by inductive coupling between a proximate object and at least one of the first inductor and the second inductor.

### BRIEF DESCRIPTION OF THE DRAWINGS

FIG. 1A illustrates an inductive alignment system including a primary coil and a first alignment coil having a mutual inductance M therebetween, according to some embodiments.

FIG. 1B illustrates an inductive alignment system, according to some embodiments.

FIGS. 2A-C illustrate multiple configurations of an inductive alignment system distributed over a plane, according to some embodiments.

FIG. 2D illustrates an inductive alignment system where one or more alignment coils may include a three-dimensional configuration of assembly coils, according to some embodiments.

FIG. 3 illustrates voltage curves for multiple alignment coils in an inductive alignment system, according to some embodiments.

FIG. 4 illustrates an inductive alignment system including a controller to provide feedback, according to some embodiments.

FIG. 5 illustrates an inductive alignment system including a controller to provide feedback and a scaling block for modifying an electrical property of one of two inductors, according to some embodiments.

FIG. 6 illustrates an inductive alignment system including a controller to provide feedback and at least one resistor for modifying an electrical property of one of two inductors, according to some embodiments.

FIG. 7 illustrates an inductive alignment system including a controller to provide feedback and two inductors coupled in parallel, according to some embodiments.

FIG. 8 is a flow chart illustrating steps in a method of inductive alignment, according to some embodiments.

In the figures, elements and steps denoted by the same or similar reference numerals are associated with the same or similar elements and steps, unless indicated otherwise.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

Embodiments of the invention as disclosed herein perform alignment of a wireless charging system without the need to generate high magnetic fields, e.g., without the need to energize coils to generate those fields. Embodiments of the invention are alternatives to alignment systems that rely on RFID, mechanical, optical, or visual apparatus, particularly in the electric vehicle market. One embodiment of the invention measures the change of the leakage induction of alignment coils with a primary side coil that is usually shorted (or effectively shorted at a given frequency) and typically in a fixed location. The relative changes in alignment coil inductance give information about the coefficient of coupling between the primary side coil and the alignment coils. This allows characterizing the position of the primary side coil relative to the alignment coils. In other words, a magnetic field in one coil induces a voltage in another coil that is measured to determine proximity; e.g., the measurements provide feedback about the proximity, which includes both distance and direction between the primary side coil and the alignment coils.

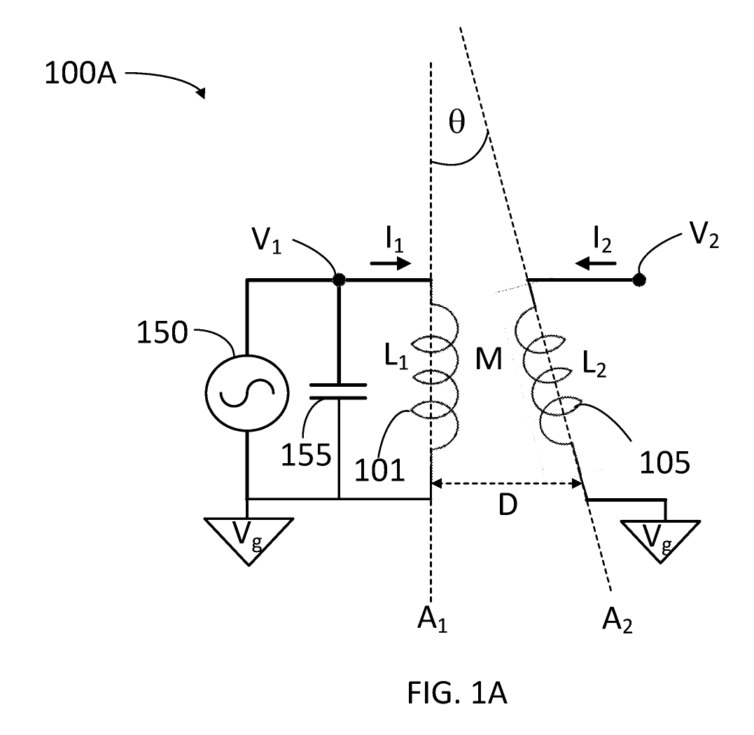

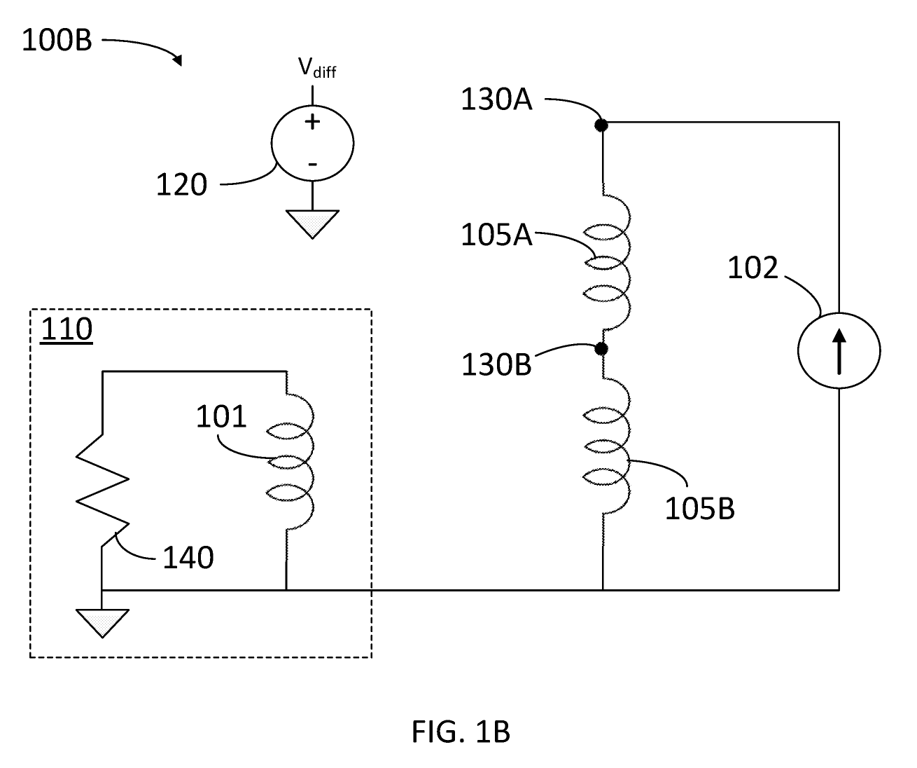

FIG. 1A illustrates an inductive alignment system 100A including a primary coil 101 having a first inductance L₁ and a first alignment coil 105 having a second inductance L₂. In general, first alignment coil 105 may be separated by a distance, D, from primary coil 101. Further, an axis A₁ through primary coil 101 may form an angle, θ, with an axis A₂ through first alignment coil 105. Inductances L₁ and L₂ mutually affect each other through a mutual inductance, M, according to some embodiments. M is typically a function of D and θ. Primary coil 101 may be powered by an alternating-current (AC) source 150, generating a voltage V₁, and a current I₁ flowing through primary coil 101. The voltage V₁ and current I₁ generate a voltage V₂ and a current I₂ through first alignment coil 105 due to the mutual inductance factor, M. Accordingly, voltages V₁ and V₂ may satisfy the following expressions:

V₁=jω(L₁·I₁+M·I₂) (1.1)

V₂=jω(M·I₁+L₂·I₂) (1.2)

Where ω is the frequency of AC source 150. System 100A includes a capacitor 155 that introduces a resonant behavior in the inductive coupling of primary coil 101 and first alignment coil 105. Accordingly, for high ω relative to 1/C (where the impedance is 1/ωC), primary coil 101 is substantially shorted down to ground voltage, V_{g} (e.g., zero)

Assuming V_{g}=0, under high frequency conditions, then, V₁ is shorted down to zero and the following is true:

$${I}_{1} = \frac{- M \cdot {I}_{2}}{{L}_{1}} \qquad ( 2 )$$

And using Eq. (2) into Eq. 1.2:

$${V}_{2} = j ω ( {L}_{2} \cdot {I}_{2} - \frac{{M}^{2} {I}_{2}}{{L}_{1}} ) = {I}_{2} \cdot j ω ( {L}_{2} - \frac{{M}^{2}}{{L}_{1}} ) \qquad ( 3 )$$

And, by analogy with Eqs. 1.1 and 1.2, an effective inductance Lₛ may be defined as:

$$\begin{matrix}{L}_{s} = {L}_{2} - \frac{{M}^{2}}{{L}_{1}} & ( 4 ) \\ Wherein & \\ {V}_{2} = {I}_{2} \cdot j ω \cdot {L}_{s} & ( 5 )\end{matrix}$$

Accordingly, Lₛ may be interpreted as the inductance measured across L₂ when primary coil 101 is shorted (e.g., at high frequencies, ω). From Eq. 4, the value of the mutual inductance, M, may be found as

M=\sqrt{L₁·(L₂−Lₛ)} (6)

A unit-less coupling coefficient, k, may be further defined as

$$k = \frac{M}{\sqrt{{L}_{1} \cdot {L}_{2}}} = \sqrt{( 1 - \frac{{L}_{s}}{{L}_{2}} )} \qquad ( 6 )$$

Measurement of Lₛ when primary coil 101 is shorted, together with prior knowledge of L₂, gives a measure of coupling coefficient, k. The coupling coefficient, k, is a unit-less value between 0 and 1, which is typically proportional to D and inversely proportional to θ. The measured inductance L₂ will change to Lₛ when primary coil 101 is shorted, which occurs under conditions where the frequency causes capacitor 155 to behave as an AC short.

System 100A depicts a configuration where source 150 would typically provide power to a remote electronic device, e.g., act as a remote power supply to charge an electric vehicle. However, during alignment, source 150 is usually disabled and a power source 102 is applied as shown in FIG. 1B.

The power source 102 provides a forcing function to a first inductor 105A. First inductor 105A exhibits a first electrical property in response to the forcing function (e.g., a measured value at probe point 130A). The power source 102 provides the forcing function to a second inductor 105B by virtue of the latter's connection to the first inductor 105A. The second inductor 105B exhibits a second electrical property in response to the forcing function (e.g., a measured value at probe point 130B). In some embodiments, first inductor 105A is coupled in series with second inductor 105B. In other embodiments the inductors 105A, 105B are coupled in parallel.

The forcing function can be a current source or a voltage source. In the case of the former, current applied to the first inductor 105A and second inductor 105B (hereinafter, collectively referred to as “inductors 105”) gives rise to voltages measured at probe points 130A, 130B. If the forcing function is a voltage source, then a current would be measured at probe points 130A, 130B. In either case, the forcing function typically operates at a frequency, co, sufficient to cause a short across the primary coil 101, potentially leaving parasitic resistance 140. The frequency is generally higher than the resonant frequency of the circuit containing the primary coil 101, e.g., 100 kHz versus 20 kHz.

Comparator 120 generates a signal based at least in part on a deviation between the first electrical property and the second electrical property. The deviation is caused at least in part by inductive coupling (e.g., through coupling coefficient, k, cf. Eq. 6) between a proximate object 110 and first inductor 105A and/or second inductor 105B. A first coupling coefficient k1 (cf. Eq. 6) may result between primary coil 101 and first inductor 105A. A second coupling coefficient, k2, may result between primary coil 101 and the second inductor 105B.

The deviation provides an indication of a difference between the two coupling coefficients k1 and k2. Further, the difference between k1 and k2 may be associated with a location of proximate object 110 relative to first alignment coil 105A and second alignment coil 105B. In some embodiments, first inductor 105A and second inductor 105B are identical coils. The first inductor 105A may be located in a predetermined location relative to the second inductor 105B, e.g., positioned at different points along an axis and/or spaced apart by a known distance. Thus, the difference between coupling coefficients k1 and k2 indicates how well the center of primary coil 101 is aligned with the axis. First inductor 105A and second inductor 105B can be placed in any arrangement where the desired axes (e.g., at least one of an X-axis, Y-axis, or Z-axis) are covered, to provide alignment guidance.

In some embodiments, the first inductor 105A and/or second inductor 105B is moving relative to proximate object 110. This might occur, for example, when one or both of the inductors 105A, 105B are included in a vehicle that is moving and will be used to align the vehicle with a charging system, e.g., the proximate object 110.

In some embodiments, at least one, or all, of power source 102, inductors 105, and comparator 120 are part of a mobile electronic appliance (e.g., a vehicle, a cell phone, a smartphone, a laptop, a tablet, or any other portable computing device). Further, in some embodiments proximate object 110 includes a stationary wireless power provider. Accordingly, inductive alignment system 100B may be configured so that the mobile electronic appliance detects proximate object 110, and determines an optimal alignment between the mobile electronic appliance with the primary coil of proximate object 110 so that a power transfer may occur between proximate object 110 and a battery in the mobile electronic appliance.

Some embodiments measure the inductance of inductors 105 as they approach or move relative to the proximate object 110, when primary coil 101 is shorted as described above. Alternatively, a second, smaller coil, coincident with the primary coil 101, can be used for alignment purposes instead of the primary coil 101, which is used for power transfer. This second coil, typically constructed using smaller wire compared to that used in primary coil 101, would be short circuited when alignment was being performed, and open circuited during power transfer. Coincidence between the primary coil 101 and the second coil can be achieved by, e.g., ensuring that both coils have the same center point.

Once a location configuration between inductors 105 and proximate object 110 is determined (e.g., an optimal alignment and proximity between inductors 105 and a primary coil 101), the short in the primary coil 101 may be removed to prevent fusing open the circuit in proximate object 110 during power transfer. Thereafter, proximate object 110 may transmit power wirelessly to the mobile electronic appliance. In other words, primary coil 101 could be shorted during alignment and driven normally during power transfer.

In some embodiments, primary coil 101 may be coupled in series with a resonant capacitor (not shown) and a power transfer inverter (e.g., AC source 150 in FIG. 1A). When the inverter is disabled (e.g., shorted), the series capacitor acts as a high frequency short. An H-bridge configuration for the power transfer inverter this can be accomplished by closing both low side switches or both high side switches in the H-bridge. This requires minimal controls using switches that are typically already present in proximate object 110.

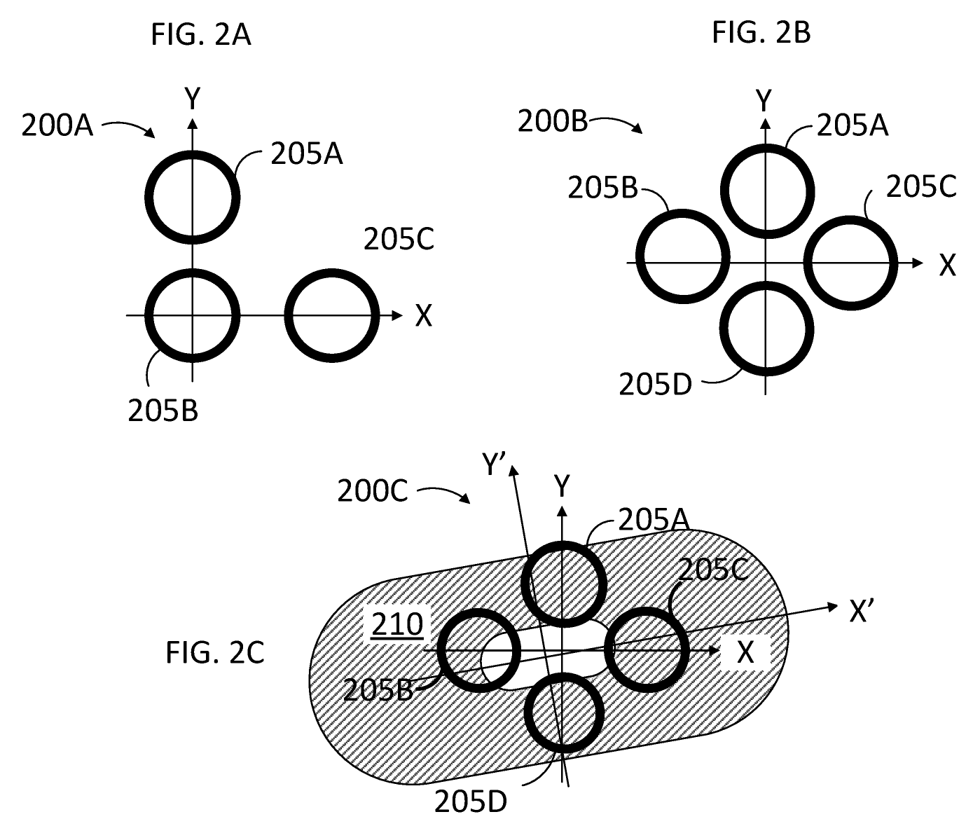

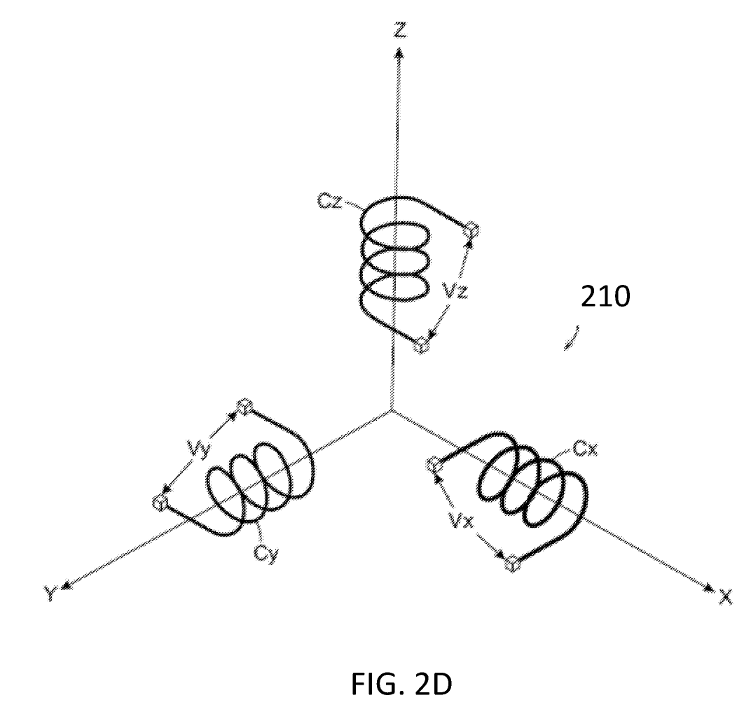

FIGS. 2A-C illustrate multiple configurations 200A, 200B, and 200C, respectively (hereinafter, collectively referred to as “configurations 200”), of an inductive alignment system distributed over a plane (defined, for illustrative purposes only, as an X-Y plane), according to some embodiments. Configuration 200A includes inductors 205A, 205B, and 205C forming a triangle configuration between axes X and Y. Configuration 200B is similar to configuration 200A, with the addition of inductor 205D to form a square arrangement in the XY plane. Inductors 205A, 205B, 205C, and 205D will be collectively referred to, hereinafter, as inductors 205.

Configuration 200C is similar to configuration 200B, with the addition of a power transfer coil 210. Power transfer coil 210 may be configured to provide wireless power to a mobile electronic appliance that includes inductors 205, when an alignment and a proximity measurement determines an optimal location configuration between the mobile electronic appliance and power transfer coil 210. Accordingly, power transfer coil 210 may have axes X′ and Y′ as magnetic symmetry axis. Note that coordinate axes X′Y′ may not only be skewed relative to axes XY, but also de-centered, thus creating asymmetric mutual inductances between power transfer coil 210 and each one of inductors 205.

In some embodiments, the relative change in inductance between inductors 205 is measured by coupling a pair of inductors along one axis in series (e.g., inductors 205A and 205B along the Y-axis in configuration 200A), and drive a fixed AC current or voltage into the series combination. The voltage across each inductor 205A or 205D will be equal when the Y-axis between inductors 205A and 205D is perfectly aligned with the Y′-axis of power transfer coil 210. The voltage across inductors 205A and 205D may be different when the Y-axis is misaligned relative to the Y′ axis of power transfer coil 210. For example, typically the inductor that is closer to the center of power transfer coil 210 will have a smaller effective inductance, and therefore will have a smaller voltage across it. A comparison between the two voltages (e.g., furnished by comparator 120, cf. FIG. 1B) can give directional information along axis Y.

Without limitation, configurations 200 may be extended to a three-dimensional alignment configuration. For example, in some embodiments, at least one of inductors 205A, 205B, 205C, and 205D includes at least three assembly coils. Each assembly coil has a longitudinal axis and is oriented orthogonally to a plane defined by the longitudinal axes of two other assembly coils (e.g., in an XYZ three-dimensional configuration). One such embodiment 210 is depicted in FIG. 2D, where three assembly coils Cₓ, C_{y}, and C_{z} are disposed orthogonally. Voltages appearing across these coils are denoted Vₓ, V_{y}, and V_{z}, respectively.

Some embodiments may include a 3-axis alignment sensor. In such configuration, three inductors may be oriented in each of the 3 axes (e.g., XYZ) with the same (or close to) origin, all with the same inductance and all connected in series. This group of three inductors would then represent a single “alignment inductor” representing a more uniform measurement of the value of coupling coefficient, k. In some embodiments, the inductor geometries for each axis may be different from each other.

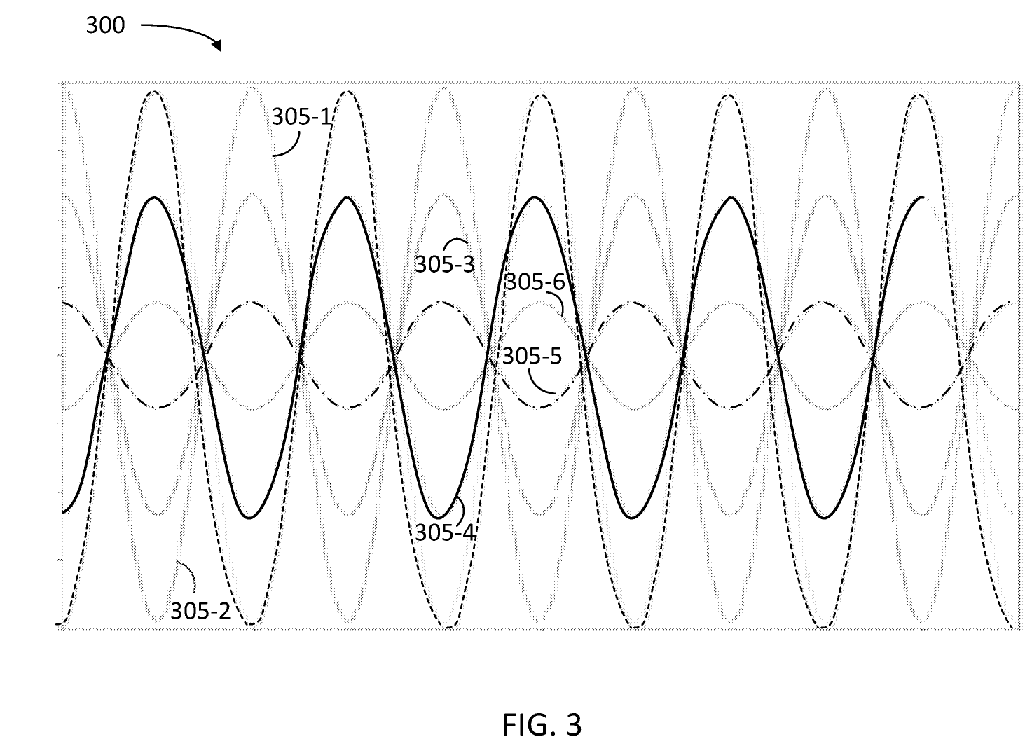

FIG. 3 illustrates chart 300 with voltage curves 305-1, 305-2, 305-3, 305-4, 305-5, and 305-6 (hereinafter, collectively referred to as “curves 305”), for multiple alignment coils in an inductive alignment system such as any of the configurations 200 (cf. FIGS. 2A-C), according to some embodiments. Any one of configurations 200 may be simulated in SPICE with the values of k for the two coils sweeping in opposite directions. In addition, curves 305 in chart 300 include a third, orthogonal axis (e.g., axis Z). Similar to configurations 200, for chart 300 a pair of inductors is symmetrically moved along each of three orthogonal axes, in opposite directions. For example, curve 305-1 corresponds to the voltage over time for inductor 205A moving along the +Y direction and curve 305-2 corresponds to the voltage over time for inductor 205D moving symmetrically, in the −Y direction. Likewise, curve 305-3 corresponds to the voltage over time for inductor 205C moving along the +X direction and curve 305-4 corresponds to the voltage over time for inductor 205B moving symmetrically, in the −X direction. Further, curve 305-5 corresponds to the voltage over time for an inductor moving along the +Z direction and curve 305-6 corresponds to the voltage over time for an identical inductor moving symmetrically, in the −Z direction. At any point in time, the difference in voltages between each of the curves 305-1 and 3052, 305-3 and 305-4, and 305-5 and 305-6 may indicate a distance of the respective inductor relative to the primary coil. Moreover, the difference between the specific values of curves 305 associated with different axes may indicate a relative orientation of the primary coil relative to the XYZ system chosen for curves 305.

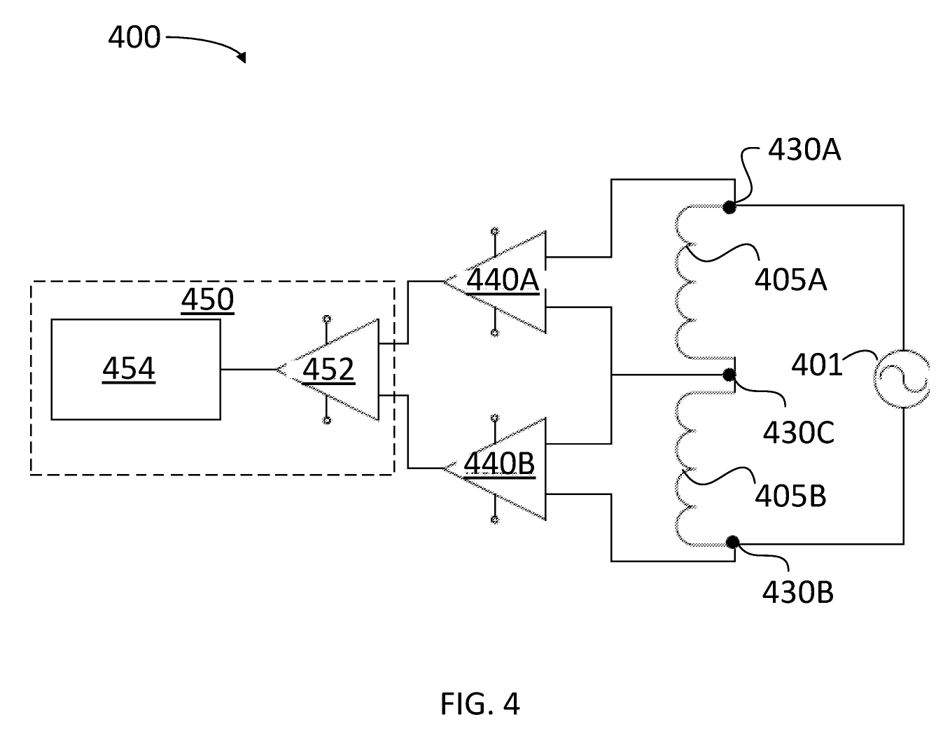

FIG. 4 illustrates an inductive alignment system 400 including a controller 450 to provide feedback through a feedback block 454 regarding the location of a first inductor 405A and/or a second inductor 405B (hereinafter, collectively referred to as “inductors 405”) relative to a proximate object including a primary coil (e.g., primary coil 101, not illustrated in the figure), according to some embodiments. Controller 450 may include a processor circuit that determines the location of the proximate object, based at least in part on the signal that comparator 452 generates.

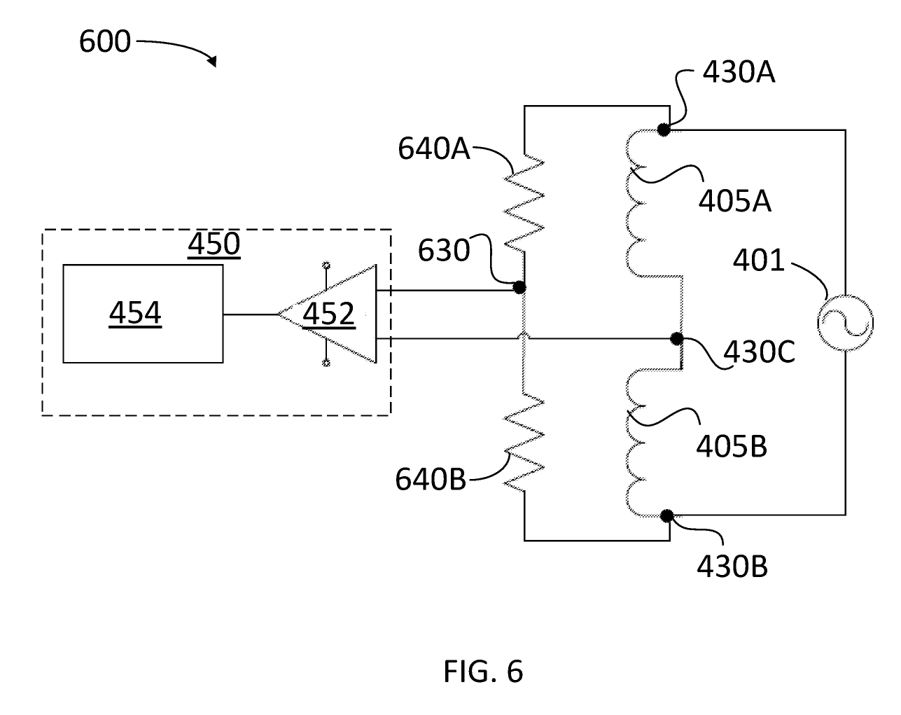

There are several ways that the comparison could be made between inductors 405. For example: controller 450 may use analog inputs from amplifying stages 440A and 440B. An amplifier 452 provides an amplified signal proportional to the difference between signals provided by amplifiers 440A and 440B to feedback block 454. In some embodiments, the comparison could be made outside controller 450. The comparison can be made directly between the voltages of inductors 405A and 405B at probe points 430A and 430B, respectively. The comparison could also be made from a center probe point 430C. The voltage at point 430C may move higher/lower but the voltage between two resistors in a similar configuration (see FIG. 6) will remain fixed as the alignment with the proximate object changes. In some configurations the high frequency AC source 401 could be either a voltage or current source.

In some embodiments, the location of the proximate object includes distance and direction information. In some embodiments, processor 450 computes a difference between (i) a first coupling coefficient that characterizes the inductive coupling between the proximate object and first inductor 405A, and (ii) a second coupling coefficient that characterizes the inductive coupling between the proximate object and second inductor 405B. In some embodiments, computation of the difference between the two coupling coefficients does not require computation of either or both coupling coefficients.

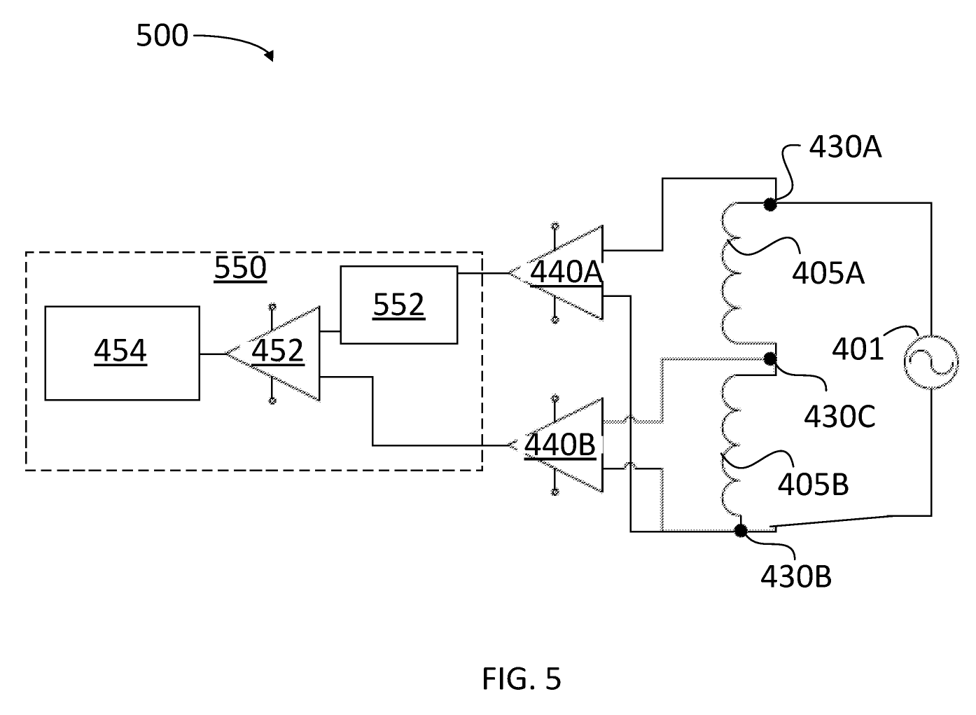

FIG. 5 illustrates an inductive alignment system 500 including a controller 550 to provide feedback through feedback block 454 regarding the location of first inductor 405A and/or second inductor 405B relative to a proximate object including a primary coil (e.g., primary coil 101, not illustrated in the figure). Inductive alignment system 500 also includes a scaling block 552 for modifying an electrical property of inductor 405A, according to some embodiments. Scaling block 552 may include an amplifier, or a current to voltage converter, or any other combination of electronic devices configured to increase or decrease the value of the electrical property of inductor 405A to a value comparable with that of inductor 405B (e.g., within the dynamic range of amplifier 452).

FIG. 6 illustrates an inductive alignment system 600 including a controller 450 to provide feedback through feedback block 454 regarding the location of first inductor 405A and/or second inductor 405B relative to a proximate object including a primary coil (e.g., primary coil 101, not illustrated in the figure). Inductive alignment system 600 includes a first resistor 640A, and a second resistor 640B (hereinafter, collectively referred to as “resistors 640”), for modifying an electrical property of inductor 405A and second inductor 405B, according to some embodiments. Further, inductive alignment system 650 includes a probe point 630 in the middle of resistors 640, which are coupled in series with each other, and in parallel with respect to inductors 405. Accordingly, amplifier 452 is fed a differential voltage between probe point 630 and probe point 430C. Therefore, movement of inductive alignment system 600 relative to the proximate object will change a voltage in point 430C but not in probe point 630.

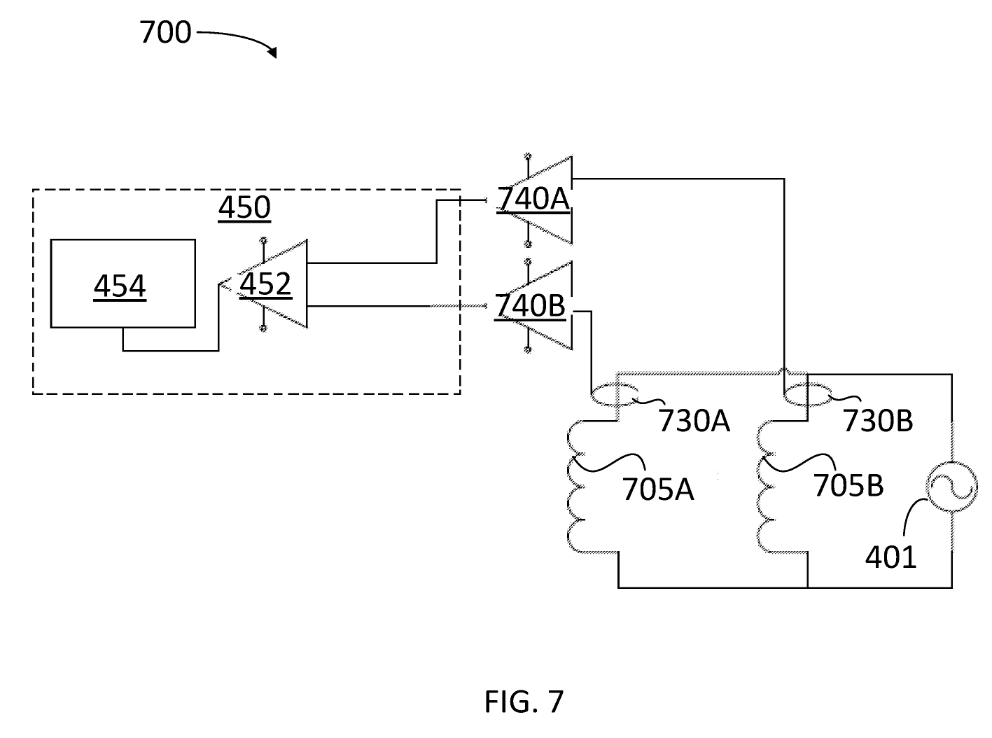

FIG. 7 illustrates an inductive alignment system 700 including a controller 450 to provide feedback through feedback block 454 regarding the location of a first inductor 705A and/or a second inductor 705B relative to a proximate object including a primary coil (e.g., primary coil 101, not illustrated in the figure). Inductive alignment system 700 includes a first inductor 705A and a second inductor 705B (hereinafter, collectively referred to as “inductors 705”) coupled in parallel, according to some embodiments.

In some embodiments, the feedback described above is used to provide information to the user of the appliance (e.g., the vehicle operator) regarding the position of the appliance (e.g., vehicle) relative to the charging station. This allows the user (e.g., operator) to move the appliance (e.g., vehicle) into proper alignment with the charging station while monitoring the feedback information. In some embodiments, the feedback information may be provided to the user (e.g., operator) as described in U.S. patent application Ser. No. 15/092,608, the contents of which are incorporated by reference herein in their entirety, for all purposes.

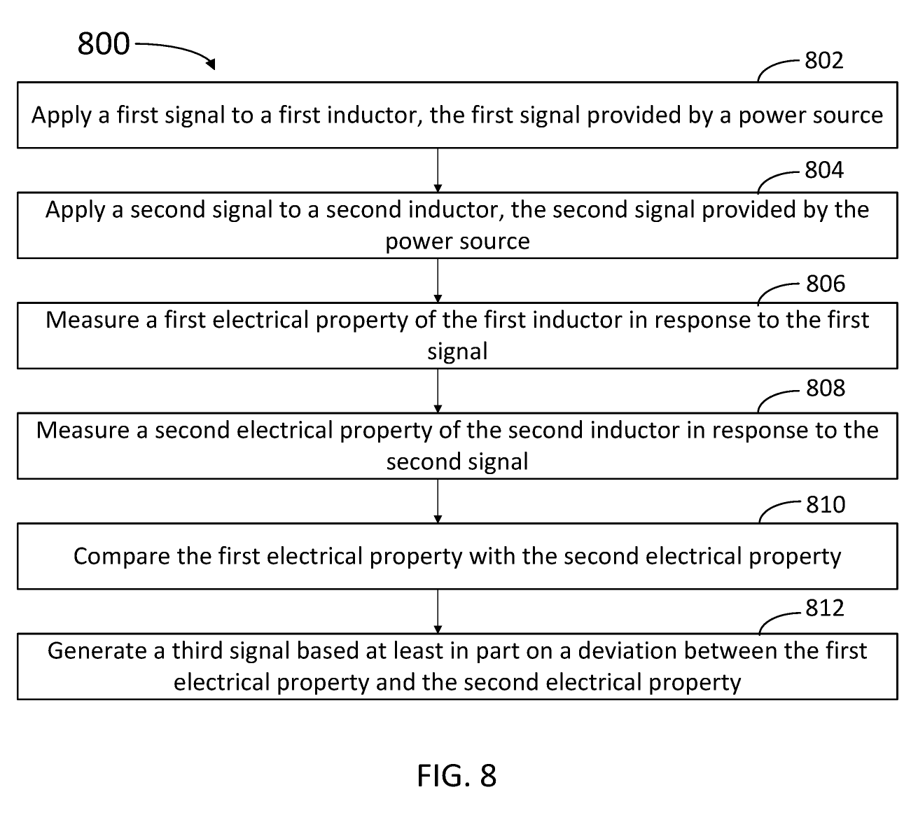

FIG. 8 is a flow chart illustrating steps in a method 800 of inductive alignment, according to some embodiments. Methods consistent with method 800 may include at least one, but not all of the steps in method 800. At least some of the steps in method 800 may be performed by a processor circuit in a computer (e.g., processor 450), wherein the processor circuit is configured to execute instructions and commands stored in a memory. Further, methods consistent with the present disclosure may include at least some of the steps in method 800 performed in a different sequence. For example, in some embodiments a method may include at least some of the steps in method 800 performed in parallel, simultaneously, almost simultaneously, or overlapping in time.

Step 802 includes applying a first signal to a first inductor, the first signal provided by a power source.

Step 804 includes applying a second signal to a second inductor, the second signal provided by the power source.

In some embodiments, the first signal may be the same as the second signal.

Step 806 includes measuring a first electrical property of the first inductor in response to the first signal.

Step 808 includes measuring a second electrical property of the second inductor in response to the second signal.

Step 810 includes comparing the first electrical property with the second electrical property.

Step 812 includes generating a third signal based at least in part on a deviation between the first electrical property and the second electrical property, wherein the deviation is caused at least in part by inductive coupling between a proximate object and at least one of the first inductor and the second inductor. In some embodiments, step 812 further includes determining a location of the proximate object relative to at least one of the location of the first inductor and the location of the second inductor, based at least in part on the third signal. In some embodiments, the location of the proximate object includes distance and direction information.

To the extent that the term “include,” “have,” or the like is used in the description or the claims, such term is intended to be inclusive in a manner similar to the term “comprise” as “comprise” is interpreted when employed as a transitional word in a claim.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. §112(f), unless the element is expressly recited using the phrase “means for” or, in the case of a method claim, the element is recited using the phrase “step for.”

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

1. An inductive alignment system, comprising:
a power source providing a forcing function;
a first inductor in communication with the power source, wherein the first inductor exhibits a first electrical property in response to the forcing function;
a second inductor in communication with the first inductor, wherein the second inductor exhibits a second electrical property in response to the forcing function; and
a comparator that compares the first electrical property with the second electrical property and generates a signal based at least in part on a deviation between the first electrical property and the second electrical property;
wherein the deviation is caused at least in part by inductive coupling between a proximate object and at least one of the first inductor and the second inductor.

2. The system of claim 1, further comprising a processor that determines a location of the proximate object relative to at least one of the location of the first inductor and the location of the second inductor, based at least in part on the signal that the comparator generates.

3. The system of claim 2, wherein the location of the proximate object comprises distance and direction information.

4. The system of claim 2, wherein the processor computes a difference between (i) a first coupling coefficient that characterizes the inductive coupling between the proximate object and the first inductor, and (ii) a second coupling coefficient that characterizes the inductive coupling between the proximate object and the second inductor.

5. The system of claim 1, wherein the first inductor is located in a predetermined location relative to the second inductor.

6. The system of claim 1, wherein at least one of the first inductor and the second inductor is moving relative to the proximate object.

7. The system of claim 1, wherein the forcing function comprises a current source.

8. The system of claim 1, wherein the forcing function comprises a voltage source.

9. The system of claim 1, wherein the proximate object comprises a third inductor.

10. The system of claim 1, wherein the first inductor is in series with the second inductor.

11. The system of claim 1, wherein the first inductor is in parallel with the second inductor.

12. The system of claim 1, wherein at least one of the first inductor and the second inductor comprises at least three assembly coils, each assembly coil having a longitudinal axis and oriented orthogonally to a plane defined by the longitudinal axes of two other assembly coils.

13. A method of inductive alignment, comprising the steps of:
applying a first signal to a first inductor, the first signal provided by a power source;
applying a second signal to a second inductor, the second signal provided by the power source;
measuring a first electrical property of the first inductor in response to the first signal;
measuring a second electrical property of the second inductor in response to the second signal;
comparing the first electrical property with the second electrical property; and
generating a third signal based at least in part on a deviation between the first electrical property and the second electrical property, wherein the deviation is caused at least in part by inductive coupling between a proximate object and at least one of the first inductor and the second inductor.

14. The method of claim 13, wherein the first signal is the same as the second signal.

15. The method of claim 13, further comprising the step of determining a location of the proximate object relative to at least one of the location of the first inductor and the location of the second inductor, based at least in part on the third signal.

16. The method of claim 15, wherein the location of the proximate object comprises distance and direction information.

17. The method of claim 13, wherein applying the first signal to the first inductor comprises applying a signal with a frequency higher than a resonance frequency of a circuit comprising a primary coil in the proximate object.

18. The method of claim 13, wherein comparing the first electrical property with the second electrical property comprises collecting the first electrical property at a first probe point in a circuit comprising the first inductor and the second inductor, and collecting the second electrical property at a second probe point in the circuit comprising the first inductor and the second inductor.

19. The method of claim 13, further comprising providing the first signal and the second signal over a range of frequencies.

20. The method of claim 13, wherein the proximate object comprises a primary coil in a circuit, the method further comprising shorting the primary coil in the circuit.
